(19) United States
(12) Patent Application Publication
(10) Pub. No.: US 2008/0070408 A1
(43) Pub. Date: Mar. 20, 2008

(54) Method for adjusting sizes and shapes of plug openings

(76) Inventors: Chin-Lung Lin, Hsinchu City (TW); Ming-Jui Chen, Tainan City (TW); Chen-yu Ao, Longjing Township (TW); Hung-Chin Thuang, Kaohsiung City (TW); Jen-Hsiang Tsai, Sihhu Township (TW); Jian-Shin Liou, Yongkang City (TW)

Correspondence Address: J.C. Patents, Inc., Suite 250, 4 Venture, Irvine, CA, 92618, US

(21) Appl. No.: 11/441,294

(22) Filed: May 24, 2006

(51) Int. Cl. H01L 21/66; H01L 21/44

(52) U.S. Cl. 438/671; 438/14; 257/E21.577; 257/E21.525

(57) ABSTRACT

The invention is directed to a method for adjusting sizes and shapes of plug openings for border plug openings overlapping with trenches respectively, wherein the border plug openings are separated from each other with a distance equal to or smaller than a specific distance. The method comprises performing an adjusting process for separating the border plug openings away from each other and enlarging the dimensions of the border plug openings so that the border plug openings are located within the trenches respectively and the edges of the borer openings are separated from the sidewalks of the trenches, wherein the border plug openings are enlarged within ranges of the trenches respectively.

### BACKGROUND OF THE INVENTION

1. Field of Invention

The present invention relates to a semiconductor process. More particularly, the present invention relates to a method for adjusting the size and the shape of a plug opening.

2. Description of Related Art

With the enhancing of the functions of the computer and the electronic product, the application circuits become complicated than ever. Based on the consideration of the cost and the stability, the integrity of the devices within the integrated circuit is greatly increased. Therefore, the surface of the wafer cannot provide enough area for manufacturing necessary interconnects thereon. In order to comply with the high demand for the interconnects as the size of the device is decreased, it is necessary to form multilayered interconnect layers so as to successfully connect the transistors to each other to form a complete electronic equipment.

In order to avoid the short circuit, it is necessary to form a dielectric material layer with a relatively better insulating ability between the interconnect layers. Taking the memory as an example, a dielectric layer with a relatively large thickness is formed to cover the memory and the contact window openings and the plug openings are formed within this thick dielectric layer.

However, with the increasing of the integrity of the device, the size of the device is decreased and the process window of the photolithography for manufacturing the aforementioned plug opening is decreased as well.

To overcome the problem mentioned above, the phase shift mask and the chromeless phase lithography are used to improve the resolution of the mask and to enhance the precision of the photolithography process. Nevertheless, the aforementioned mask is very expensive and the outcome is not as good as it is expected. Hence, the aforementioned problem cannot be effectively solved.

Moreover, if the misalignment happens during the photolithography process is performed to form the via opening or the contact window opening, the short circuit is generated due to the narrow distance between the adjacent plugs or between the plug and the conductive line.

Furthermore, the size of the plug is decreased, that is, the cross-sectional area of the plug opening is decreased so that the contact resistance of the plug is increased. Therefore, the rate of the current transmission is decreased so that the operation speed of the device is decreased.

### SUMMARY OF THE INVENTION

Accordingly, at least one objective of the present invention is to provide a method for adjusting a size and a shape of a plug opening capable of increasing the process window to avoid the short circuit happening between the plug and the conductive line and to decrease the contact resistance between the plug and the conductive line.

At least another objective of the present invention is to provide a method for adjusting a size and a shape of a plug opening capable of performing an adjusting process on plug openings at different locations.

To achieve these and other advantages and in accordance with the purpose of the invention, as embodied and broadly described herein, the invention provides a method for adjusting a size and a shape of a plug opening for a first border plug opening and a second border plug opening overlapping with a first trench and a second trench respectively, wherein the first trench and the second trench are located adjacent to each other and a smallest distance between a first edge of the first border plug opening and a second edge of the second border plug opening is equal to or smaller than a specific distance. The method comprises a steps of performing an adjustment process for separating the first border plug opening from the second border plug opening and enlarging at least one of the first border plug opening and the second border plug opening so that the first border plug opening and the second border plug opening are located within the first trench and the second trench respectively and the first edge and the second edge are separated from the sidewalls of the first trench and the second trench respectively, wherein the dimensions of the enlarged first border plug opening or the enlarged second border plug opening are within a first range of the first trench and a second range of the second trench respectively.

According to one embodiment of the present invention mention above, the first trench and the second trench are located over the first border plug opening and the second border plug opening respectively.

According to one embodiment of the present invention mention above, the first trench and the second trench have a conductive layer formed therein.

According to one embodiment of the present invention mention above, the first border plug opening and the second border plug opening are located over the conductive layer.

According to one embodiment of the present invention mention above, the adjustment process comprises an optical proximity correction.

According to one embodiment of the present invention mention above, the adjustment process comprises a design rule check.

According to one embodiment of the present invention mention above, the method for enlarging at least one of the first border plug opening and the second border plug opening comprises enlarging a lateral dimension and a vertical dimension of one of the first border plug opening and the second border plug opening according to the same enlarging proportion.

According to one embodiment of the present invention mention above, the method for enlarging at least one of the first border plug opening and the second border plug opening comprises enlarging a lateral dimension and a vertical dimension of one of the first border plug opening and the second border plug opening according to different enlarging proportion.

According to one embodiment of the present invention mention above, the adjustment process further comprises shrinking a dimension of a center plug opening located between the first trench and the second trench along a direction perpendicular to both axes of the first trench and the second trench.

According to one embodiment of the present invention mention above, the method further comprises a step of shrinking a lateral dimension and a vertical dimension of the center plug opening according to different shrinking proportion.

According to one embodiment of the present invention mention above, the method further comprises a step of shrinking a lateral dimension and a vertical dimension of the center plug opening according lo the same shrinking proportion.

The present invention also provides a method for adjusting sizes and shapes of plug openings. The method comprises steps of classifying a plurality of plug openings into a plurality of types which at least include border plug openings and center plug openings. The border plug openings at least partially overlap with trenches respectively, wherein the trenches are located adjacent to each other and a smallest distance between edges of the border plug openings is equal lo or smaller than a specific distance. The center plug openings are located between the adjacent trenches. Then, an adjustment process is performed. The adjustment process comprises steps of separating the border plug openings away from each other and enlarging the dimensions of the border plug openings so that the border plug openings are located within the trenches respectively and the edges of the borer openings are separated from the sidewalls of the trenches, wherein the border plug openings are enlarged within ranges of the trenches respectively. Edges of the center plug openings are separated away from the sidewalls of the trenches which are located adjacent lo the center plug openings respectively.

According to one embodiment of the present invention mention above, the trenches are located over the border plug openings.

According to one embodiment of the present invention mention above, the trenches have a conductive layer formed therein.

According to one embodiment of the present invention mention above, the border plug openings are located over the conductive layer.

According to one embodiment of the present invention mention above, the adjustment process comprises an optical proximity correction.

According to one embodiment of the present invention mention above, the adjustment process comprises a design rule check.

According to one embodiment of the present invention mention above, the method for enlarging the border plug openings comprises enlarging a lateral dimension and a vertical dimension of the border plug openings according to the same enlarging proportion.

According to one embodiment of the present invention mention above, the method for enlarging the border plug openings comprises enlarging a lateral dimension and a vertical dimension of the border plug openings according to different enlarging proportion.

According to one embodiment of the present invention mention above, the method for making edges of the center plug openings away from the sidewalls of the trenches comprises shrinking a dimension of a center plug opening located between trenches along a direction perpendicular to axes of the trenches.

According to one embodiment of the present invention mention above, the method for shrinking the center plug openings comprises a lateral dimension and a vertical dimension of the center plug opening according to the same shrinking proportion.

According to one embodiment of the present invention mention above, the method for shrinking the center plug openings comprises a lateral dimension and a vertical dimension of the center plug opening according to different shrinking proportion.

In the present invention, the aforementioned method for adjustment sizes and shapes of the plug openings can be done by using the design of the manufacturing process to perform optical proximity correction or design rule check on the plug openings in different locations. Therefore, the process window can be increased and the short circuit problem between the later formed plug and the conductive lines can be avoided. Furthermore, the sizes of the plug openings are enlarged to increase the contact areas between the plug and the conductive lines so as to decrease the conduct resistance between the plug and the conductive lines.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing a method for adjusting a size and a shape of a plug opening according to a preferred embodiment of the invention.

FIG. 2A is a top view showing a size and a shape of a plug opening before an adjustment process is performed according to one preferred embodiment of the invention.

FIG. 2B is a top view showing a size and a shape of a plug opening after an adjustment process is performed according to one preferred embodiment of the invention.

### DESCRIPTION OF THE PREFERRED EMBODIMENTS

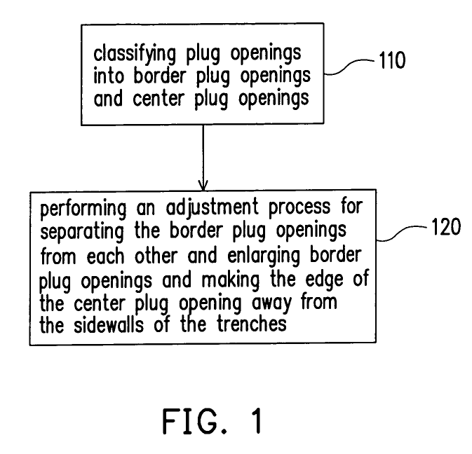

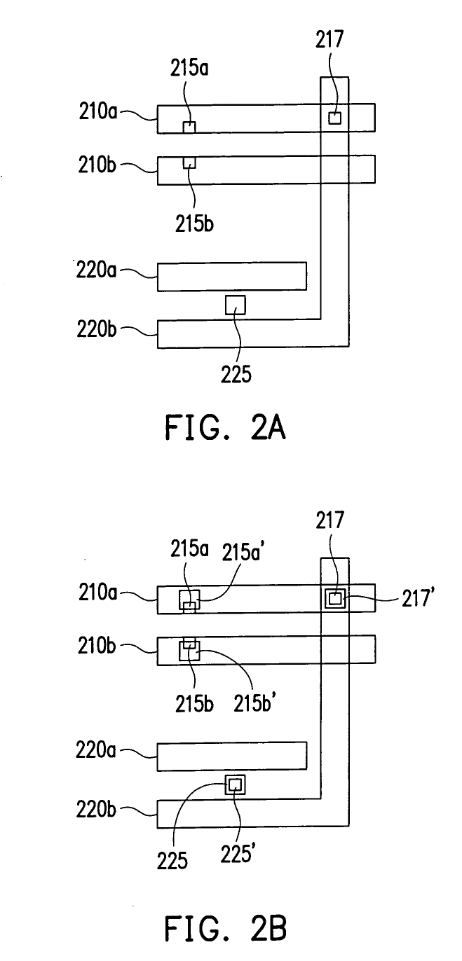

FIG. 1 is a flow chart showing a method for adjusting a size and a shape of a plug opening according to a preferred embodiment of the invention. FIG. 2A is a top view showing a size and a shape of a plug opening before adjusted according lo one preferred embodiment of the invention. FIG. 2B is a top view showing a size and a shape of a plug opening after adjusted according to one preferred embodiment of the invention.

As shown in FIG. 1 and FIG. 2A, first of all, several plug openings are classified (step 110). The plug openings at least can be classified into two types. One type includes plug openings, such as border plug openings 215a and 215b which at least overlap with the adjacent trenches 210a and 210b respectively and are located apart from each other with a distance between the closest edges of the plug openings, wherein the distance is equal to or smaller than a specific distance. The other type is a plug opening, such as center plug opening 225 located between adjacent trenches 220a and 220b.

One edge of each of the border plug openings 215a and 215b can be, for example, overlaps with one edge of each of the trenches 210a and 210b respectively. Alternatively, the space between the border plug openings 215a and 215b is smaller than or equal to a specific distance. Furthermore, the border plug openings 215a and 215b partially overlap with the trenches 210a and 210b respectively. Because these openings are filled with conductive material to form vias or contact windows in later performed process, it is highly possible lo generate the short circuit problem between the later formed plugs if the border plug openings 215a and 215b are close to each other.

The trenches 210a and 210b can be, for example, located above the border plug openings 215a and 215b. Alternatively, the trenches 210a and 210b can be, for example, filled with conductive material to be the conductive lines (not shown) and the border plug openings 215a and 215b are located on the conductive lines to expose a portion of the conductive lines. Depending on the actual needs for the design layout, he border plug openings 215a and 215b can be, for example, via openings or contact window openings.

Certainly, the trenches 210a and 210b not only have border plug openings 215a and 215b located therein but also have other plug openings, such as the plug opening 217 shown in FIG. 2, located therein.

The center plug opening 225 can be, for example, located between another pair of adjacent trenches 220a and 220b. However, the present invention is not limited to the description herein. The trenches 220a and 220b can be, for example but not limited to, filled with conductive material to be the conductive lines. Since the integrity of the device is high, the distance between the trenches 220a and 220b is small. Therefore, the position alignment shifting of the center plug opening due to the error of the photolithography process easily happens during the center plug opening is formed between the trenches 220a and 220b. Accordingly, the short circuit between the later formed plug and the conductive lines happens.

As shown in FIG. 2B, an adjustment process is performed to move away the border plug openings 215a and 215b from each other so that the moved border plug openings 215a′ and 215b′ are located in the trenches 210a and 210b respectively and are away from the sidewalls of the trenches 210a and 210b respectively. Moreover, within the ranges of the trenches 210a and 210b, at least one of the sizes of the border plug openings 215a′ and 215b′ is enlarged (as shown in FIG. 2B, the border plug opening 215a′ and 215b′ are both enlarged). Furthermore, the size or the shape of the center plug opening 225 is adjusted to apart away from the adjacent sidewalks of the trenches 220a and 220b (step 120) so as to form a center plug opening 225′.

The adjustment process can be done by using the optical proximity correction technology or the design rule check to adjust the positions of the border plug openings 215a and 215b so that the sidewalls of the border plug openings 215a and 215b do not overlap with the edges of the trenches 210a and 210b respectively. Accordingly, the border plug openings 215a and 215b can overlap with the trenches 210a and 210b respectively in a manner of being located completely within the trenches 210a and 210b. The method for enlarging the border plug opening 215b can be, for example, performed by magnifying the lateral dimension and the vertical dimension of the border plug opening simultaneously according to the same magnifying proportion. Alternatively, the lateral dimension and the vertical dimension of the border plug opening can be enlarged according to different magnifying proportion. Certainly, it is possible to enlarge either lateral dimension or vertical dimension. As for the other plug opening within the trench, such as the plug opening 217, it can be also enlarged simultaneously so as to form a plug opening 217′. After the adjustment process is performed, the size and the shape of the adjusted border plug openings 215a and 215b are shown in FIG. 2B.

The method for separating apart the center plug opening 225 from the sidewalls of the adjacent trenches 220a and 220b can be done by using the optical proximity correction technology or the design rule check as well to shrink the dimension of the center plug opening 225 along a direction perpendicular to the major axes of the adjacent trenches 220a and 220b. Certainly, the lateral dimension and the vertical dimension of the center plug opening 225 can be shrunk according to the same shrinking proportion. Alternatively, the lateral dimension and the vertical dimension of the center plug opening 225 can be shrunk according to different shrinking proportions. It is possible to shrink either lateral dimension or vertical dimension.

By shrinking the dimension of the center plug opening 225 between the trenches 220a and 220, the short circuit problem happening between the later formed plug and the conductive line can be effectively avoided. Hence, the reliability and the stability of the device can be improved.

After the adjustment process, the distance between the edges of the border plug openings 215a 1 and 215b′ is increased. Therefore, no short circuit phenomenon happens between the later formed plugs. Additionally, since the sizes of the border plug openings 215a′ and 215b′ and the plug opening 217′ which are located within the trenches 210a and 220b are enlarged, the contact areas between the plugs and the conductive lines are increased. Hence, the contact resistances between the plugs and the conductive lines are decreased.

Besides, by using the design rule of the manufacturing process, the optical proximity correction technology or the design rule check are performed on the border plug openings 215a and 215b so as to enlarge the dimensions of the openings. Therefore, the process windows of different openings can be increased so that the manufacturing process can be well controlled and can be well improved to face the next generation technology challenge.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for adjusting a size and a shape of a plug opening for a first border plug opening and a second border plug opening overlapping with a first trench and a second trench respectively, wherein the first trench and the second trench are located adjacent to each other and a smallest distance between a first edge of the first border plug opening and a second edge of the second border plug opening is equal to or smaller than a specific distance, the method comprising:
performing an adjustment process for separating the first border plug opening from the second border plug opening and enlarging at least one of the first border plug opening and the second border plug opening so that the first border plug opening and the second border plug opening are located within the first trench and the second trench respectively and the first edge and the second edge are separated from the sidewalls of the first trench and the second trench respectively, wherein the dimensions of the enlarged first border plug opening or the enlarged second border plug opening are within a first range of the first trench and a second range of the second trench respectively.

2. The method of claim 1, wherein the first trench and the second trench are located over the first border plug opening and the second border plug opening respectively.

3. The method of claim 1, wherein the first trench and the second trench have a conductive layer formed therein.

4. The method of claim 3, wherein the first border plug opening and the second border plug opening are located over the conductive layer.

5. The method of claim 1, wherein the adjustment process comprises an optical proximity correction.

6. The method of claim 1, wherein the adjustment process comprises a design rule check.

7. The method of claim 1, wherein the method for enlarging at least one of the first border plug opening and the second border plug opening comprises enlarging a lateral dimension and a vertical dimension of one of the first border plug opening and the second border plug opening according to the same enlarging proportion.

8. The method of claim 1, wherein the method for enlarging at least one of the first border plug opening and the second border plug opening comprises enlarging a lateral dimension and a vertical dimension of one of the first border plug opening and the second border plug opening according to different enlarging proportion.

9. The method of claim 1, wherein the adjustment process further comprises shrinking a dimension of a center plug opening located between the first trench and the second trench along a direction perpendicular to both axes of the first trench and the second trench.

10. The method of claim 9 further comprising a step of shrinking a lateral dimension and a vertical dimension of the center plug opening according to different shrinking proportion.

11. The method of claim 9 further comprising a step of shrinking a lateral dimension and a vertical dimension of the center plug opening according to the same shrinking proportion.

12. A method for adjusting sizes and shapes of plug openings, comprising:
classifying a plurality of plug openings into a plurality of types which at least include:
border plug openings at least partially overlapping with trenches respectively, wherein the trenches are located adjacent lo each other and a smallest distance between edges of the border plug openings is equal lo or smaller than a specific distance; and
center plug openings located between the adjacent trenches; and performing an adjustment process comprising:
separating the border plug openings away from each other and enlarging the dimensions of the border plug openings so that the border plug openings are located within the trenches respectively and the edges of the borer openings are separated from the sidewalls of the trenches, wherein the border plug openings are enlarged within ranges of the trenches respectively; and
making edges of the center plug openings away from the sidewalls of the trenches which are located adjacent to the center plug openings respectively.

13. The method of claim 12, wherein the trenches are located over the border plug openings.

14. The method of claim 12, wherein the trenches have a conductive layer formed therein.

15. The method of claim 14, wherein the border plug openings are located over the conductive layer.

16. The method of claim 12, wherein the adjustment process comprises an optical proximity correction.

17. The method of claim 12, wherein the adjustment process comprises a design rule check.

18. The method of claim 12, wherein the method for enlarging the border plug openings comprises enlarging a lateral dimension and a vertical dimension of the border plug openings according to the same enlarging proportion.

19. The method of claim 12, wherein the method for enlarging the border plug openings comprises enlarging a lateral dimension and a vertical dimension of the border plug openings according to different enlarging proportion.

20. The method of claim 12, wherein the method for making edges of the center plug openings away from the sidewalls of the trenches comprises shrinking a dimension of a center plug opening located between trenches along a direction perpendicular to axes of the trenches.

21. The method of claim 20, wherein the method for shrinking the center plug openings comprises a lateral dimension and a vertical dimension of the center plug opening according to the same shrinking proportion.

22. The method of claim 20, wherein the method for shrinking the center plug openings comprises a lateral dimension and a vertical dimension of the center plug opening according to different shrinking proportion.
